(19) United States
(12) Patent Application Publication
(10) Pub. No.: US 2007/0281086 A1
(43) Pub. Date: Dec. 6, 2007

(54) Apparatus and method for producing carbon nanotubes

(75) Inventor: Bor-Yuan Hsiao, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI Precision Industry CO., LTD., Tu-Cheng City (TW)

(21) Appl. No.: 11/447,482

(22) Filed: Jun. 5, 2006

(51) Int. Cl. C23C 16/00

(52) U.S. Cl. 427/249.1; 977/843; 118/723 E

(57) ABSTRACT

An exemplary apparatus for producing carbon nanotubes includes a reaction chamber, a first electrode, a second electrode, and a driving element. The first electrode and the second electrode are arranged inside the reaction chamber and configured for creating an electric field in the reaction chamber. The first electrode is configured for holding a substrate for growing carbon nanotubes thereon. The second electrode is arranged facing the first electrode. The driving element is configured for driving one of the first electrode and the second electrode to move along a direction parallel to a growth direction of the carbon nanotubes.

### CROSS-REFERENCE TO RELATED APPLICATION

This application is related to a copending U.S. patent application Ser. No. ______ filed ______ (Attorney Docket No. US7487) entitled “APPARATUS AND METHOD FOR PRODUCING CARBON NANOTUBES” with the same assignee. The disclosure of the above-identified application is incorporated herein by reference.

### TECHNICAL FIELD

The present invention relates to apparatuses and methods for producing carbon nanotubes, and more particularly to an apparatus and a method for producing carbon nanotubes using chemical vapor deposition.

### BACKGROUND

Carbon nanotubes are a relatively new material having a hollow tubular structure composed of carbon atoms. Carbon nanotubes have excellent electrical, magnetic, nonlinear optical, thermal, and mechanical properties, possessing a high Young's modulus, a high elastic modulus, and a low density Depending on their length, diameter, and mode of spiraling, carbon nanotubes can exhibit metallic or semiconductor-like properties. They are widely used in a variety of fields, such as nanometer-scale electronics, materials science, biological science, and chemistry.

At present, methods for producing carbon nanotubes include arc discharge, pulsed laser vaporization, and chemical vapor deposition. The chemical vapor deposition method generally uses transition metals or oxides as a catalyst to grow carbon nanotubes at high temperature by decomposition of carbon-containing reactive gases. Compared with these two methods, the chemical vapor deposition method is superior in operational simplicity, low cost, and mass production, therefore the chemical vapor deposition method has become widely used.

A typical chemical vapor deposition method for producing carbon nanotubes includes the steps of: providing a substrate coated with a catalyst layer on a surface; putting the substrate in a reaction device; heating the reaction device; introducing a carbon-containing reactive gas and thereby growing carbon nanotubes on the substrate.

However, after using a typical method to produce carbon nanotubes for about 5 to 30 minutes, the rate of precipitation of carbon becomes greater than that of diffusion of carbon. Thus, the catalyst particles become blocked by accumulation of the decomposed carbon of the carbon-containing reactive gas. Therefore, the carbon nanotubes stop growing at a short length.

What is needed, therefore, is an apparatus and a method for producing carbon nanotubes that can have greater length and good collimation.

### SUMMARY

In a preferred embodiment, an apparatus for producing carbon nanotubes includes a reaction chamber, a first electrode, a second electrode, and a driving element. The first electrode and the second electrode are arranged inside the reaction chamber and are configured for creating an electric field in the reaction chamber. The first electrode is configured for holding a substrate for growing carbon nanotubes thereon. The second electrode is arranged facing the first electrode. The driving element is configured for driving one of the first electrode and the second electrode to move along a direction parallel to a growth direction of the carbon nanotubes.

In another preferred embodiment, a method for producing carbon nanotubes includes the steps of: providing a reaction chamber; providing a substrate having a catalyst layer thereon; arranging them in the reaction chamber; introducing a carbon-containing reactive gas into the reaction chamber; creating an electric field in which the substrate is disposed; growing carbon nanotubes using chemical vapor deposition; and moving the substrate along a direction parallel to a growth direction of the carbon nanotubes.

Other advantages and novel features will become more apparent from the following detailed description of the present apparatus and method for producing carbon nanotubes when taken in conjunction with the accompanying drawings.

### BRIEF DESCRIPTION OF THE DRAWINGS

Many aspects of the apparatus and method for producing carbon nanotubes can be better understood with reference to the following drawings. The components in the drawings are not necessarily drawn to scale, the emphasis instead being placed upon clearly illustrating the principles of the present invention. Moreover, in the drawings, like reference numerals designate corresponding parts throughout the several views.

FIG. 1 is a schematic view of an apparatus for producing carbon nanotubes, in accordance with a first preferred embodiment; and

FIG. 2 is a schematic view of an apparatus for producing carbon nanotubes, in accordance with a second preferred embodiment.

### DETAILED DESCRIPTION OF PREFERRED EMBODIMENTS

Reference will now be made to the drawing figures to describe the preferred embodiment of the present apparatus and method for producing carbon nanotubes in detail.

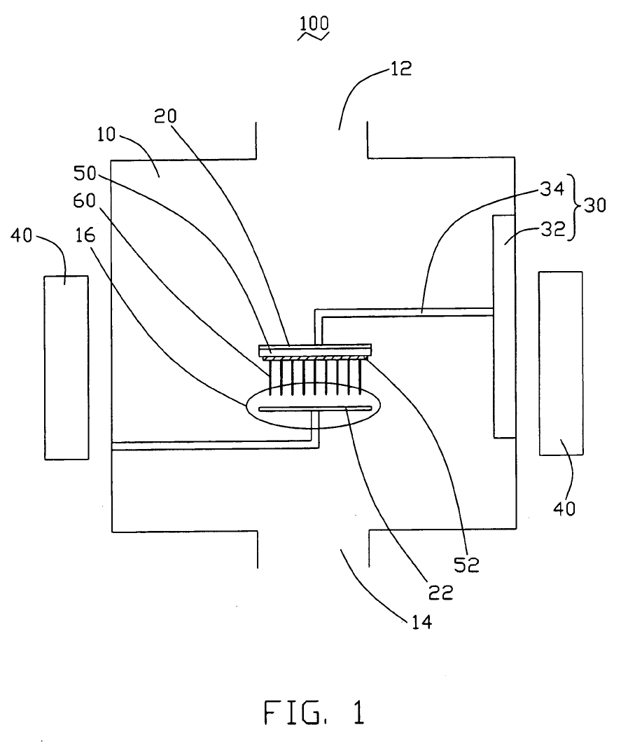

Referring to FIG. 1, an apparatus 100 for producing carbon nanotubes in accordance with a first preferred embodiment is shown. The apparatus 100 includes a reaction chamber 10, a first electrode 20, a second electrode 22 facing the first electrode 20, a driving element 30, and a heating element 40.

The reaction chamber 10 comprises a gas inlet port 12 and a gas outlet port 14 at two opposite ends of the reaction chamber 10. At least one carbon-containing reactive gas or a mixture of the reactive gas and a carrier gas is introduced into the reaction chamber 10 through the gas inlet port 12. The reactive gas which is not reacted is discharged from the gas outlet port 14. Typically, the gas inlet port 12 is disposed at the upper end of the reaction chamber 10 and the gas outlet port 14 is disposed at the bottom end.

The first electrode 20 and the second electrode 22 are located inside the reaction chamber 10. The first electrode 20 is moveable and can move toward to or away from the second electrode 22. The second electrode 22 remains stationary. The first electrode 20 is used to support a substrate 50 for growing carbon nanotubes thereon.

The driving element 30 is configured to move the first electrode 20 up and/or down in the reaction chamber 10. The driving element 30 comprises a guide rail 32 and a cantilever 34. The guide rail 32 is located on the inner wall of the reaction chamber 10. One end of the cantilever 34 is disposed on the guide rail 32 and the other end is connected with the first electrode 20. A motor can drive the cantilever 34 to slide along the guide rail 32. Therefore, the first electrode 20 can be moved up and/or down in the reaction chamber 10 by the cantilever 34.

The heating element 40 is arranged around the reaction chamber 10 for heating the reaction chamber 10. The heating element 40 is either a high temperature furnace or a high frequency furnace (e.g. a microwave furnace).

The apparatus 100 uses the driving element 30 to lift the substrate 50 held by the first electrode 20. The micro tips of the carbon nanotubes 60 are kept in a reactive region 16, and growth of the carbon nanotubes 60 is thereby maintained. When a voltage is applied between the first electrode 20 and the second electrode 22, an electric field is generated. The growth direction of carbon nanotubes 60 is parallel to the direction of the electric field, giving the carbon nanotubes 60 good collimation as a result.

The reactive region 16 is defined as a region suitable for carbon nanotubes 60 growth. The temperature of the reactive region 16 is in the range from about 500 to 900 degrees centigrade. The position of the reactive region 16 in the reaction chamber 10 is relatively constant. In the reactive region 16, the rate of precipitation of carbon is less than that of the diffusion of carbon. Therefore, the catalyst particle surface does not become blocked by accumulation of decomposed carbon from the carbon-containing reactive gas. Therefore, the carbon nanotubes 60 are allowed to grow to a greater length.

A method for producing carbon nanotubes using the apparatus 100 is described in detail below.

The substrate 50 having a catalyst layer 52 is held by the first electrode 20. The surface of the catalyst layer 52 faces the second electrode 22. The substrate 50 is made of a material selected from the group consisting of silicon, quartz, and glass. The catalyst layer 52 is made of a material chosen from the group consisting of iron, cobalt, nickel, and an alloy including at least two of the three. The catalyst layer 52 can be deposited by, for example, an ion deposition method, a radio frequency sputtering method, a vacuum vapor method, or a chemical vapor deposition method.

A voltage is applied between the first electrode 20 and the second electrode 22, thereby generating an electric field. The carbon nanotubes 60 are good electrical conductors and will, therefore grow in parallel with the direction of the electric field.

A carbon-containing reactive gas is introduced into the reaction chamber 10, the heating element 40 heats the substrate 50 to a predetermined temperature, for example, about 500 to 900 degrees centigrade, thereby producing carbon nanotubes 60 through chemical vapor deposition. During the growth of the carbon nanotubes 60, the driving element 30 moves the first electrode 20 away from the second electrode 22. At the high temperature, the carbon-containing reactive gas decomposes and carbon atoms are released from the reactive gas and deposited onto the catalyst layer 52. Thus, the carbon nanotubes 60 grow from the catalyst layer 52. During the growth of the carbon nanotubes 60 the driving element 30 moves the first electrode 20, thereby keeping the micro tips of the carbon nanotubes 60 in the reactive region 16.

The carbon-containing reactive gas could be introduced into the reaction chamber 10 with a carrier gas. The reactive gas is selected from the group consisting of methane, acetylene, ethylene, carbon monoxide, and any suitable mixture thereof The carrier gas is selected from the group consisting of hydrogen, helium, argon, ammonia, and any suitable combination thereof

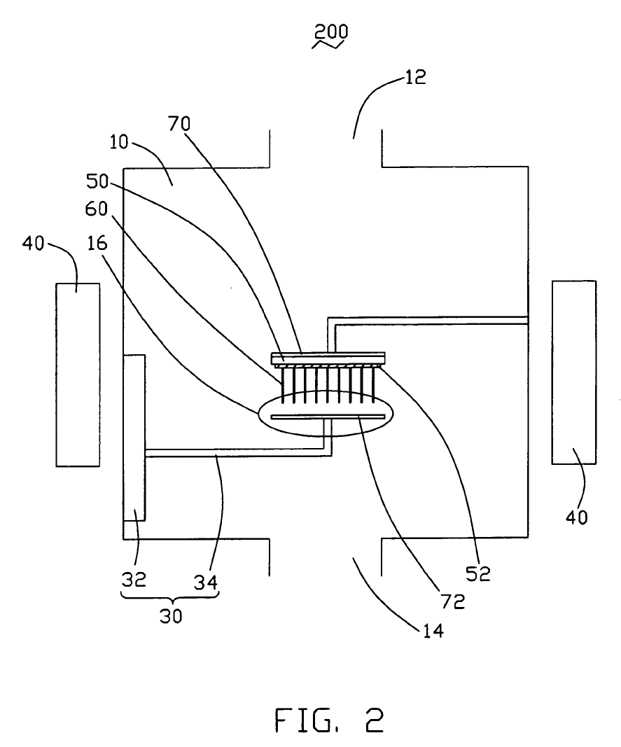

Referring to FIG. 2, an apparatus 200 for producing carbon nanotubes in accordance with a second preferred embodiment is shown. The structure of the apparatus 200 is similar to that of the apparatus 100. The apparatus 200 includes a reaction chamber 10, a first electrode 70, a second electrode 72 facing the first electrode 70, a driving element 30, and a heating element 40.

In the illustrated embodiment, the first electrode 70 is stationary, whilst the second electrode 72 is moveable relative to the first electrode 70. The first electrode 70 is used to support the substrate 50 for growing carbon nanotubes 60. The driving element 30 is configured for moving the second electrode 72 up and/or down in the reaction chamber 10. The cantilever 34 is disposed on the guide rail 32 and is connected with the first electrode 20. Therefore, the second electrode 72 can move along a growth direction of the carbon nanotubes 60.

Although the present invention has been described with reference to specific embodiments, it should be noted that the described embodiments are not necessarily exclusive, and that various changes and modifications may be made to the described embodiments without departing from the scope of the invention as defined by the appended claims.

What is claimed is:

1. An apparatus for producing carbon nanotubes, comprising:
a reaction chamber;
a first electrode arranged inside the reaction chamber, the first electrode being configured for holding a substrate for growing carbon nanotubes thereon,
a second electrode arranged facing the first electrode, the first and second electrode being configured for creating an electric field in which the substrate is disposed; and
a driving element configured for driving one of the first electrode and the second electrode to move along a direction parallel to a growth direction of the carbon nanotubes.

2. The apparatus as claimed in claim 1, wherein the first electrode is moveable along a direction opposite to a growth direction of the carbon nanotubes.

3. The apparatus as claimed in claim 1, wherein the first electrode is stationary related to the reaction chamber, and the second electrode is moveable relative to the first electrode along a growth direction of the carbon nanotubes.

4. The apparatus as claimed in claim 1, wherein the driving element comprises a guide rail and a cantilever having a first end slidably engaged in the guide rail, the guide rail is arranged in the reaction chamber and an opposite second end of the cantilever is connected to one of the first electrode and the second electrode.

5. The apparatus as claimed in claim 1, wherein the reaction chamber comprises a gas inlet port and a gas outlet port at opposite sides thereof.

6. The apparatus as claimed in claim 1, further comprising a heating element configured for elevating a temperature of an interior of the reaction chamber.

7. The apparatus as claimed in claim 6, wherein the heating element is one of a high temperature furnace and a high frequency furnace.

8. A method for producing carbon nanotubes comprising the steps of:
providing a reaction chamber;
providing a substrate having a catalyst layer thereon;
arranging the substrate in the reaction chamber;
introducing a carbon-containing reactive gas into the reaction chamber;
creating an electric field in which the substrate is disposed;
growing carbon nanotubes using chemical vapor deposition; and
moving the substrate along a direction parallel to a growth direction of the carbon nanotubes.

9. The method as in claimed in claim 8, further comprising the steps of providing a first electrode and a second electrode, and applying a voltage between the first electrode and the second electrode.

10. The method as in claimed in claim 8, further comprising a step of heating an interior of the reaction chamber.

11. The method as in claimed in claim 10, wherein the carbon-containing reactive gas is introduced into the reaction chamber with a carrier gas.

12. The method as in claimed in claim 11, wherein the reactive gas is selected from the group consisting of methane, acetylene, ethylene, carbon monoxide, and a suitable mixture thereof.

13. The method as in claimed in claim 11, wherein the carrier gas is selected from the group consisting of hydrogen, helium, argon, and ammonia.

14. The method as claimed in claim 8, wherein the catalyst layer is formed by a method selected from the group consisting of ion beam deposition, radio frequency sputtering, vacuum vapor deposition, and chemical vapor deposition.

15. An apparatus for producing carbon nanotubes, comprising:
a reaction chamber;
a substrate holding member disposed in the reaction chamber, the substrate holding member configured for holding a substrate for growing carbon nanotubes thereon;
a driving member disposed in the reaction chamber, the driving member configured for driving the substrate holding member to move along a direction parallel to a growth direction of the carbon nanotubes in the reaction chamber;
a first electrode; and
a second electrode opposite the first electrode; the first and second electrodes configured for creating an electric field in which the substrate is disposed.

16. The apparatus as claimed in claim 15, wherein the electric field is oriented in the direction opposite to the growth direction of the carbon nanotubes.
